(19) United States
(12) Patent Application Publication
(10) Pub. No.: US 2025/0081707 A1
(43) Pub. Date: Mar. 6, 2025

(54) FULLY METALLIC ATOMIC-SCALE TIN TRANSISTORS WITH ULTRALOW POWER DISSIPATION

(71) Applicant: PATENTPOOL Innovations Management GmbH, Munich (DE)

(72) Inventors: Fangqing Xie, Karlsruhe (DE); Thomas Schimmel, Karlsruhe (DE)

(21) Appl. No.: 18/727,578

(22) PCT Filed: Jan. 2, 2023
(86) PCT No.: PCT/EP2023/050022

§ 371 Date: Jul. 9, 2024

(30) Foreign Application Priority Data
Jan. 10, 2022 (EP) 22150675.1

(51) Int. Cl. H10K 10/84; H10K 10/46

(52) U.S. Cl. CPC H10K 10/84; H10K 10/464; H10K 10/488

(57) ABSTRACT

An atomic-scale tin transistor device with ultralow power dissipation and a method for producing the same and its use. An atomic-scale tin transistor device includes a source electrode, a drain electrode, and a gate electrode. The source, drain, and gate electrodes are spaced apart from one another and immersed in an aqueous electrolyte containing tin ions in an electrochemical cell. The source electrode and drain electrode are connected to each other in an on-state by a bistable atomic-scale tin point-contact which can be reversibly opened and closed by dissolution/deposition potentials applied to the gate electrode, respectively.

The present invention relates to an atomic-scale tin transistor device with ultralow power dissipation and a method for producing the same and its use.

Information and communication technology (ICT) has spread into all aspects of social society. Therefore, its energy consumption in devices and services has become of strategic importance and a sustainable issue for modern society. The energetics issue of ICT in the current and future raises a question of the ultimate energy efficiency of digital logic computation based on complementary metal-oxide-semiconductor (CMOS) technology. The advanced CMOS technology now faces a grand power consumption challenge due to a stagnation in the scaling of the supply voltage and the channel length. Yet, the lowering of the supply voltage and overall power consumption is precluded by the subthreshold swing of a metal-oxide-semiconductor field-effect transistor (MOSFET) which is found to be at 60 mV/decade and room temperature. These values are defined by the transport mechanism of CMOS devices based on thermionic emission over the barrier with fundamental thermionic limits (so-called Boltzmann tyranny). More precisely, the total switching energy (Eₜₒₜₐₗ) of a logic operation can be found as the sum of the dynamic, leakage, and interconnect components versus V_{DD} as shown by the following Equation (1):

$${E}_{total} = {E}_{dynamic} + {E}_{leakage} + {E}_{interconnect} \approx {L}_{d} {{CV}_{DD}}^{2} ( ∝ + 10 \frac{- {V}_{DD}}{S} ) + ∝ {C}_{interconnect} {{V}_{DD}}^{2} \qquad ( 1 )$$

where L_{d} is the logic depth, C is the switched capacitance, V_{DD} is the supply voltage, a is the logic activity factor (typically ˜0.01), and S is the subthreshold swing. Equation (1) indicates that the most effective way to control the power density is to scale down the supply voltage. The only way to decisively break the power dissipation bottleneck is to change the operation mechanism of a transistor in ways that facilitate the further reduction of operating voltage.

Considerable preliminary research has already been done on the fabrication of contacts between individual atoms, which is achieved in a mechanical way, whereby thin metallic bridges will be stretched out to such an extent that the contact area will be made up of a single or a few atoms in diameter. While such contacts frequently but not always turn out to be quantum point contacts having conductance values of integer multiples of the conductance quantum, their conductance values, which they adapt, can hardly be predetermined or adjusted beforehand on a predefined value. In fact, the conductance value of the metallic bridge is decreasing when its diameter is decreasing successively, mostly in several stages, until the bridge is breaking. The essential problem of the implementation of atomic or molecular electronics, i.e., the implementation of active components which made it possible by means of an independent third control electrode to control and adjust specifically the conductance value between source and drain electrode, is not yet solved therewith.

In the past there had been two approaches for solving this problem. In one approach, an atomic contact was repeatedly opened and closed while two macroscopic electrodes were moved towards one another and afterwards moved away from another and thus, requiring the movement of a macroscopic electrode. As for the second approach, D. Eigler et al., Nature 352 (1991) 600, succeeded in switching the position of a single atom in a tunneling microscope between two positions (on the tip of the tunnel and on the surface of the sample). In this case there is a component the only movable or moved part of which is a single atom. This atom flip-flop has not only the disadvantage that it operates in the shown configuration only at low temperatures (typically at 4 K up to 30 K) and in ultra-high vacuum, i.e., not under conditions where in technical applications electronic relays operate. Moreover, there is also no independent third electrode as a control electrode or gate available, instead the switching of the atom position of the movable atom is achieved by applying a potential to both electrodes the conductance value of which has to be switched. However, first and foremost, this arrangement does not allow to open and close an electrical circuit, but the resistance of the contact typically varies between 0% and 40% due to the switching of the position of the atom, whereby this percentage of variation cannot be predicted exactly.

A method of forming a channel layer of an electric device with metals such as gold, silver, platinum, aluminum, lead, hafnium, tantalum, copper, tin, or palladium is disclosed in US 2014/080274 A1. A tunneling current from a conductive substrate was suggested to reduce metal ions in an electrolyte. According to Equation (5) mentioned in the following, the tunneling current is exponentially dependent on the thickness of the insulating layer. Therefore, the tunneling current should be in the picoampere range. The device has four terminals and one power supply. However, the method was not demonstrated to be implementable experimentally.

A different approach has been described by the present inventors in F.-Q. Xie et al. Physical Review Letters 93, 128303 (2004) and in WO 2006/026961 A2, disclosing metallic atomic-scale transistors operated with a novel fundamental switching paradigm. Specifically, a gate-controlled atomic switch is disclosed which comprises three electrodes: a source electrode, a drain electrode and a gate electrode, said source electrode and said drain electrode being connected to each other by means of an electrically conductive bridge made up of one or several silver (Ag) atoms which can be reversibly opened and closed; the opening and closing of the contact between said source electrode and said drain electrode being controllable by a potential applied to said gate electrode. That is, the only moveable elements of the atomic switch are the contacting Ag atoms and the electrical contact (gate) between the two electrodes which are called source and drain. This gate-controlled atomic switch operates at room temperature and without exclusion of oxygen. Instead of an aqueous silver nitric electrolyte (silver nitrate and nitric acid) used in WO 2006/026961 A2, the atomic-scale silver transistor can also be operated in a quasi-solid-state gel electrolyte made of a mixture of colloidal pyrogenic silica and an aqueous solution of silver nitrate and nitric acid as disclosed in Advanced Materials 30, 1801225 (2018) by Fangqing Xie et al. Besides this silver atomic-scale transistor that operates in an aqueous nitric electrolyte at voltages in the millivolt range (a few hundred millivolts), copper (Cu) and lead (Pb) atomic-scale transistors have been reported by F. Q. Xie et al. in Physical Review B 95, 195415 (2017), and Beilstein Journal of Nanotechnology 8, 530-538 (2017). However, the energy needed for switching in terms of the absolute value of the electrochemical potential to be applied to the gate electrode of the Cu atomic-scale transistors and Pb atomic-scale transistors are still in the range of a few hundred millivolts and several tens of millivolts, respectively. Another drawback of these transistors is the limitation as to the material of the source and drain electrodes. Only gold electrodes are reported for the atomic-scale Ag/Cu/Pb transistors. Moreover, the present inventors have investigated the atomic-scale point-contacts of gold and palladium electrochemically and found no bistable configurations in their atomic-scale point-contacts, which is a necessary property as working materials for metallic atomic-scale transistors operated electrochemically.

In view of the above, it is an object of the present invention to overcome the above drawbacks and to provide a transistor device which should have a reduced power dissipation, specifically allowing a further reduction of the operating voltage (e.g., in the range of few millivolts) needed to switch the transistor from the off-state to the on-state and vice versa, and which should be available at lower costs and under safer conditions.

The above technical problem underlying the present invention has been solved by providing the embodiments characterized in the appended claims.

In particular, the present invention provides an atomic-scale tin transistor device which comprises a source electrode; a drain electrode; and a gate electrode, wherein the source, drain, and gate electrodes are spaced apart from one another and immersed in an aqueous electrolyte containing tin ions in an electrochemical cell, wherein the source electrode and drain electrode are connected to each other in the on-state by a bistable atomic-scale tin point-contact which can be reversibly opened and closed by dissolution/deposition potentials applied to the gate electrode, respectively, and wherein the atomic-scale tin point-contact consists in the on-state at its narrowest point of at least one tin atom up to a few hundreds of tin atoms formed by electrochemical deposition of tin.

Surprisingly, the operation potential of the atomic-scale tin transistor device according to the present invention can be 10 times lower than that of the above-mentioned atomic-scale Ag transistor disclosed in F.-Q. Xie et al. Physical Review Letters 93, 128303 (2004) and in WO 2006/026961 A2. Notably, the power dissipation is proportional to the square of the operation potential. Advantageously, the atomic-scale tin transistor device according to the present invention has also a short channel length, high drain-source current (as high as several hundred microampere (μA) in magnitude), and low dynamic energy.

Furthermore, the on/off potentials are much lower than the constraint on the signal voltage swing (35.8 mV) of CMOS digital logic circuits by Landauer's limit and even smaller than the “action potentials” of neuron fire (−20 to −100 mV) in magnitude (cf. also O. Liu et al., Cell. 2018, 175, 57-70. e17). The Landauer's limit is described in IBM Journal of research and development, “Irreversibility and heat generation in the computing process” 5, 183-191 (1961) as follows: V_{DD}≥2 (In2)k_{B}T/e=35.8 mV,

where k_{B} represents the Boltzmann constant, T=300 K, and e the electron charge.

The low on/off potentials in the atomic-scale tin transistor according to the present invention can reduce the energy consumption in the interconnects of integrated circuits at least by about 400 times in comparison with the digital logic circuits based on the CMOS technology. The conductance at on-states of the bistable configurations of the inventive transistor device has been demonstrated to vary between 1.2 G₀ to 197 G₀ (G₀=2e2 h⁻¹, wherein e represents the electron charge and h the Planck's constant). The drain-source current (I_{DS}) at the on-state (197 G₀) reaches about −375 μA when the drain-source dc voltage (U_{DS}) is set at −25 mV.

In the atomic-scale tin transistor according to the present invention, tin atoms as information carriers are considerably different from electrons or spins due to their natural weight and size. According to the Wentzel-Kramers-Brillouin approximation, the natural weight of tin atoms makes the channel length 3 nm or less, preferably even less than 1 nm.

Furthermore, the metallic property of the tin point-contact in the atomic-scale tin transistor of the present invention ensures high electrical current transport. The low on/off potentials of the transistor depend on the electrochemical characterization of metallic tin. Unlike the CMOS devices, the bit value is presented by the conductance of the atomic-scale tin point-contact in the transistor. Therefore, its information carriers are atoms instead of electrons. However, in this case, information is easily transferred back to the electrical domain, where nearly all information processing takes place today. Therefore, the atomic-scale tin transistor according to the present invention fulfills the requirements on an electronic device with ultralow power dissipation as a sustainable alternative to CMOS devices.

Besides, the atomic-scale tin transistor device is environmentally friendly and safe due to the non-toxic property of tin.

According to the present invention, the atomic-scale tin transistor device can be manufactured by a method comprising repeatedly applying potential cycles between the gate electrode and the source or drain electrode, respectively, for repeatedly depositing and dissolving tin atoms between the source electrode and drain electrode until the bistable atomic-scale tin point-contact has been formed, wherein the potential during the potential cycles is increased and subsequently lowered as long as due to the change of the potential at the gate electrode, the conductance value between the source electrode and the drain electrode can reproducibly be switched between two conductance values as a function of the potential of the gate electrode.

That is, the fundamental idea of the manufacturing process according to the invention is the training of an electrochemically produced atomic point-contact by repeated cycling in the following manner.

Firstly, tin is galvanically deposited from the electrolyte in a small space (gap) between the source electrode and drain electrode until the contact between the two electrodes is closed and a preset upper conductance value X is exceeded. Specifically, during the deposition of tin, the source and drain electrodes become thicker and wider. Consequently, the gap between the two electrodes becomes narrower until, finally, a tin point-contact is formed in the gap. The deposition continues until the preset upper conductance value X is exceeded to stabilize the point-contact. Simultaneously, a tin film is deposited on the gate electrode by grounding the gate electrode. After the stabilizing procedure, the gate electrode is disconnected from the ground and electrically suspended in the electrolyte in order to prevent tin dissolution from the gate during the following training procedure. Then, immediately or with a defined time delay, a dissolution potential V2 is applied to the source and drain electrodes relative to the gate electrode (for instance, but not necessarily, by varying the potential of the quasi-reference electrode relative to a reference potential “ground” and not the potential of the source and drain electrodes) until the conductance value falls short of a lower conductance value Y, and then a deposition potential V1 will be applied again until in the contact the upper conductance value is reached and the cycle of applying the dissolution potential V2 starts again.

After some time of training, the junction geometries become increasingly stable and alternate between two stable conformations by variation of the electrochemical potential applied to the gate electrode. That is, this procedure (also called training of the tin point-contact) is repeated until the conductance value between the source electrode and the drain electrode can reproducibly and stably be switched between two conductance values as a function of the potential of the gate electrode. This behavior of the atomic-scale tin point-contact is referred to as “bistable”, meaning that the system has two stable equilibrium states. By snapping into “magic” bistable conformations, junctions are mechanically and thermally stable at room temperature for long sequences of switching cycles, which offers interesting technological perspectives. The cyclic deposition/dissolution procedure thus trains the initially built atomic-scale tin transistor with the feedback mechanism, which is similar to the one previously described for the atomic-scale Ag and Pb transistors. Thus, the disclosure of WO 2006/026961 A2 relating to the training procedure is incorporated herein by reference. The tin transistor can thus perform conductive switching between the on/off states within the tin point-contact with a bistable configuration with dissolution/deposition potentials in millivolts applied to the gate electrode.

In a preferred embodiment, the bistable atomic-scale tin point-contact in the on-state at its narrowest point consists of only one tin atom or of a few tin atoms, and by means of the tin transistor device an electrical circuit can be opened or closed through conductive switching between on/off states within the atomic-scale tin point-contact with a bistable configuration by deposition/dissolution potentials in millivolts applied to the gate electrode, which changes the position of a single tin atom or a few tin atoms in the bistable atomic-scale tin point-contact. According to the present invention, the “on-state” thus refers to a state where the source electrode and the drain electrode are electrically connected to each other by the bistable atomic-scale tin point-contact, whereas the “off-state” refers to a state where the bistable atomic-scale tin point-contact between the source electrode and the drain electrode is opened, i.e., there is a gap between the source and drain electrodes.

Preferably, the cycling process is carried out between two or more specified gate electrode potentials, wherein the potential is varied in a rectangular, triangle, trapezoid, or sinusoidal waveform.

According to a preferred embodiment, the source and drain electrodes contain at least one metal selected from the group consisting of copper (Cu), ruthenium (Ru), rhodium (Rh), palladium (Pd), osmium (Os), iridium (Ir), platinum (Pt), gold (Au), and silver (Ag). These metals are also referred to as noble metals within the present invention. That is, the source and drain electrodes of the atomic-scale tin transistor device can be made of any noble metal, preferably selected from gold, silver, platinum, and copper. In contrast, for the atomic-scale Ag and Cu transistors, only gold and platinum can be used as working materials for the source and drain electrodes. Accordingly, according to the present invention, cheaper metals as working materials for the source and drain electrodes can be used.

In this context, it should be noted that the source and drain electrodes may be insulated with a polymer, for instance, except for a small window crossing both electrodes for the electrochemical deposition of tin.

The source and drain electrodes can be fabricated using lithographic methods. Specifically, the source and drain electrodes may be deposited by known methods on an insulating substrate. The substrate is not particularly limited as long as it is electrically insulating and can receive the electrodes. Examples of suitable materials for the substrate include silicon wafers and glass substrates without being limited thereto.

Preferably, the gate electrode consists of a tin wire or a metal film covered with a layer of tin. Specifically, the gate electrode may consist of a tin wire having a diameter of 0.5 mm, for instance, such as Puratronic® (99.9985%), or of a noble metal film covered with a layer of tin.

According to a preferred embodiment of the present invention, the electrolyte is an aqueous electrolyte comprising tin salts and acids such as SnSO₄+H₂SO₄, SnCl₂+HCl, Sn(NO₃)₂+HNO₃, and SnSO₄+HBO₃. According to the present invention, the electrolyte may be liquid or may be incorporated into a polymer or a porous, micro-porous or nano-porous system. Also, it is contemplated that the electrolyte is an aqueous ionic liquid.

According to the present invention, the source, drain, and gate electrodes are immersed in the electrolyte containing tin ions in an electrochemical cell. The electrochemical cell can be made of any materials such as glass, ceramic, and polymers, and the dimensions can vary from millimeters to hundred nanometers.

According to the present invention, because the tin atoms are information carriers instead of electrons, the conductive channel length of the atomic-scale tin transistor device is preferably 3 nm or less, more preferably 1 nm or less. Preferably, the only movable parts of the atomic-scale tin transistor device are the tin atoms, which connect the source and drain electrodes. It is also preferable that the potential applied during the switching process will be given automatically by a control circuit or a signal source.

In addition to the low channel length, the atomic-scale tin transistor according to the present invention can be operated at ultralow operation voltage. Preferably, the gate potential is less than 35 mV in magnitude, more preferably 20 mV or less, most preferably 15 mV or less. As mentioned above, the electrochemical potential applied to the gate electrode can be 2.5 mV or less in absolute, which is much lower than the minimal level on the supply voltage of a CMOS digital logic circuit set by Landauer's limit (35.8 mV).

Further, the on-state conductance can vary between 1.2 G₀ to 197 G₀. Also, it is preferred that the tunneling current at the off-state is less than 10 nA, more preferably a few nA, specifically less than 5 nA.

According to the present invention, drain-source current at on-state is preferably a few hundreds of μA, specifically 250 μA or more in magnitude, preferably 300 μA or more in magnitude, and most preferably 350 μA or more in magnitude.

The minimal switching-on energy of the transistor device according to the present invention is preferably 0.34 eV (13.1 k_{B}T at 300 K). The minimal switching-on energy is about 18.9 times larger than the ultimate limit on the minimum energy per switching at k_{B}TIn2 (Landauer's limit, approximately 3×10⁻²¹ J at room temperature). The maximal switching-on energy is estimated to be 3.99 eV (154.2 k_{B}T at 300 K).

As mentioned above, the conductance of the tin point-contact as a physical state variable can reside in two distinguishable on/off states. It can be controlled between the on/off states (write) by the gate potential, read by an electrical current through the tin point-contact, transmitted from one physical location to another via the electrical current, and initialized in a defined state (erase) just by setting the gate potential. The conductance of the tin point-contact as a state variable may compete with the thermal noise bath at room temperature.

The atomic-scale tin transistor device according to the present invention may be used in various forms, such as an atomic transistor or atomic relay, specifically for switching an electrical circuit by the atomic-scale tin transistor. It may be used for logic switches and/or carrying out logic operations. The transistor or relay may be used in the range of ultra-high frequencies from the megahertz range over the gigahertz range to the terahertz range. In addition, the atomic-scale tin transistor device according to the present invention may be used as building blocks of atom-based electronics.

In addition, the atomic-scale tin transistor can operate at room temperature or at temperatures between −30° C. and +50° C., which meets the usual standards of the specification of the operation temperature of electronic components.

In the following, embodiments of the present invention are described in detail with reference to the accompanying Figures which show:

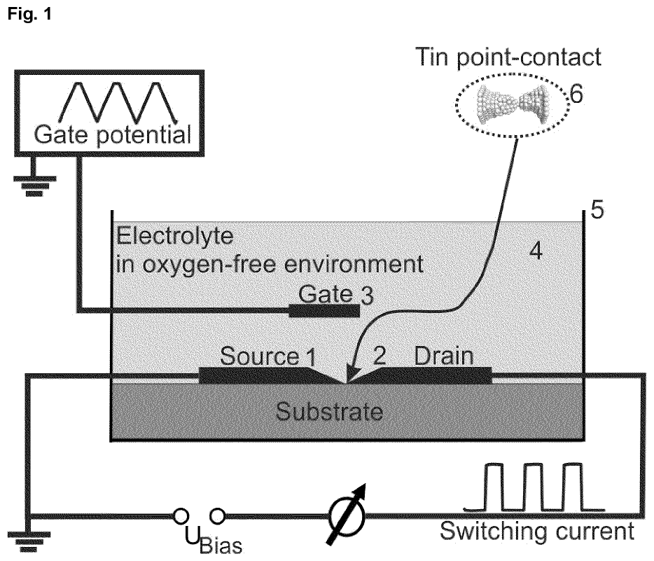

FIG. 1: A schematic diagram of an atomic-scale tin transistor according to the present invention.

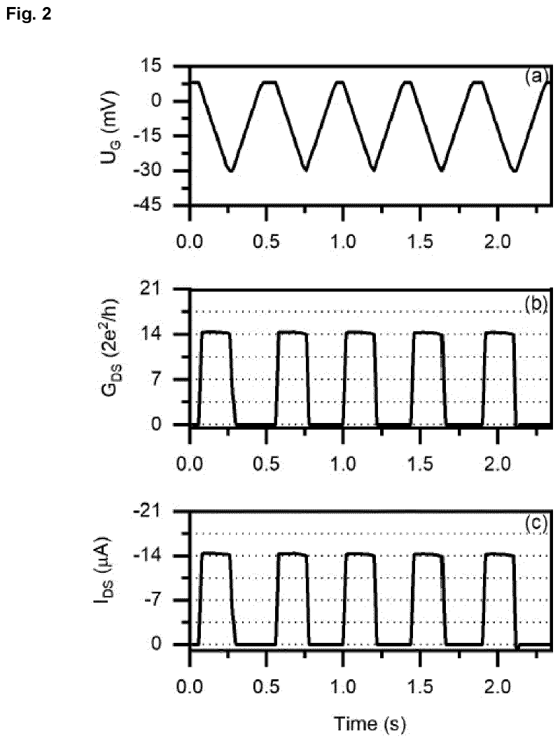

FIG. 2: A quantum conductance switching controlled via the feedback mechanism. The top (a) shows the ramping wave between 8 and −30 mV which expresses the potential change on the gate, the middle (b) shows a digital graph which presents the conductance variation (0-14 G₀) following the gate potential, and the bottom (c) is a rectangular curve which shows the corresponding current from 0 to −14 μA measured with U_{DS} set to −12.9 mV.

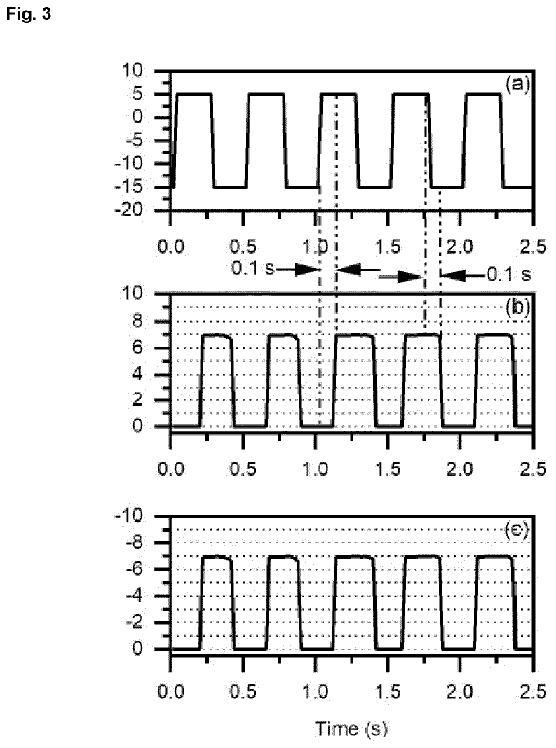

FIG. 3: A function-generator-controlled quantum conductance switching between 0 and 7 G₀. The upper (a) shows the rectangular wave between 5 and −15 mV which illustrates the potential applied to the gate by the virtual function generator, and the middle (b) digital signal exhibits quantum conductance switching between 0 and 7 G₀ succeeding the gate potential with a delay at 0.1 s. At the same time, the lower (c) rectangular wave demonstrates the corresponsive current variation in a digital form between 0 and −7 μA when U_{DS} is set at −12.9 mV.

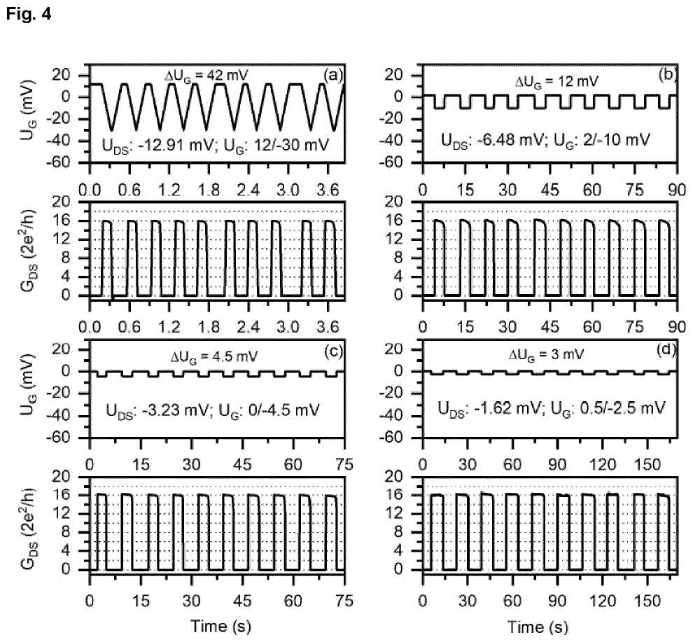

FIG. 4: Potential differences between the gate, source, and drain determined through U_{DS} and the gate potential U_{G} of an embodiment of the present invention.

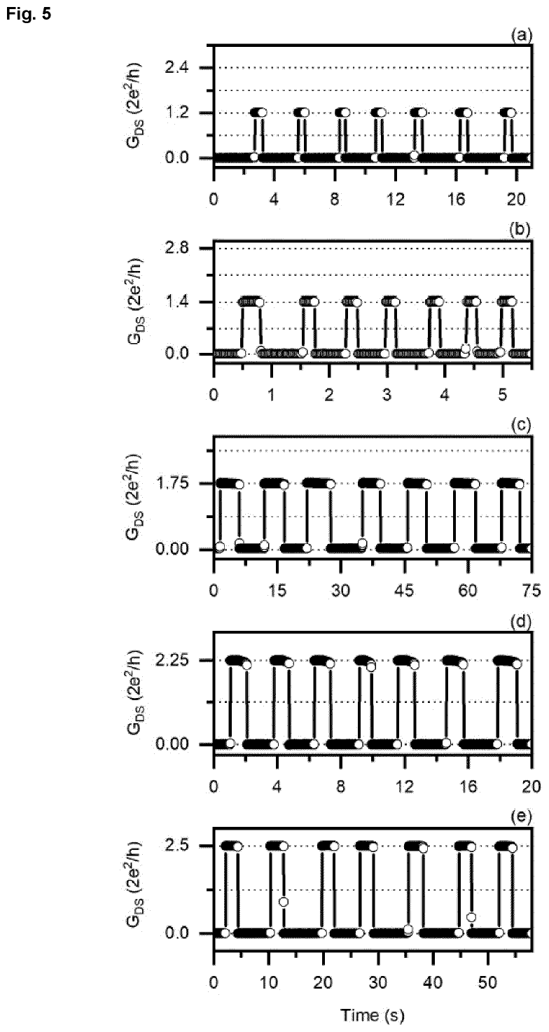

FIG. 5: Demonstration of bistable conductive switching between 0 and different non-integer quantum conductance levels of an embodiment of the present invention.

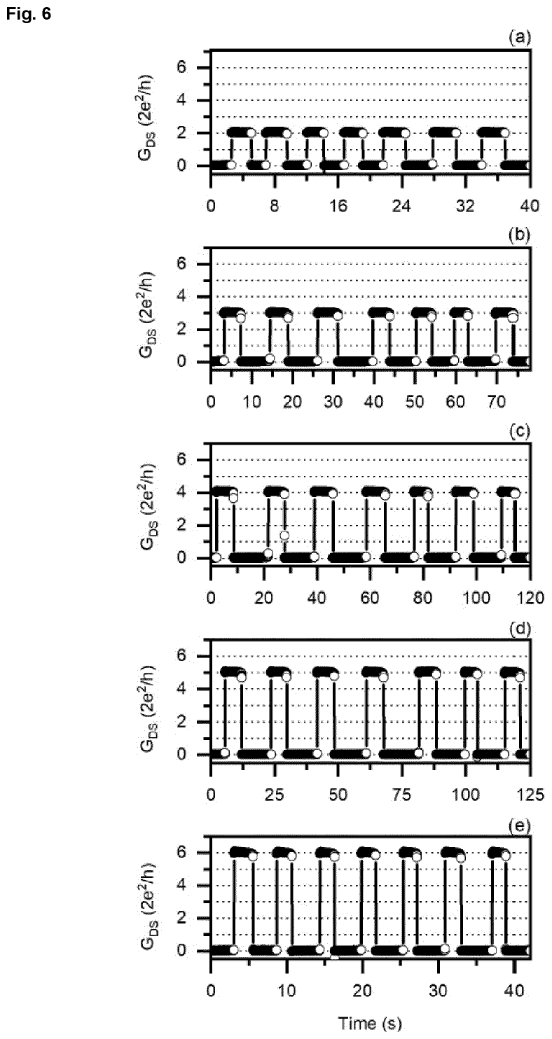

FIG. 6: Demonstration of bistable conductive switching between 0 and different integer quantum conductance levels (from 2 G₀ to 6 G₀) of an embodiment of the present invention.

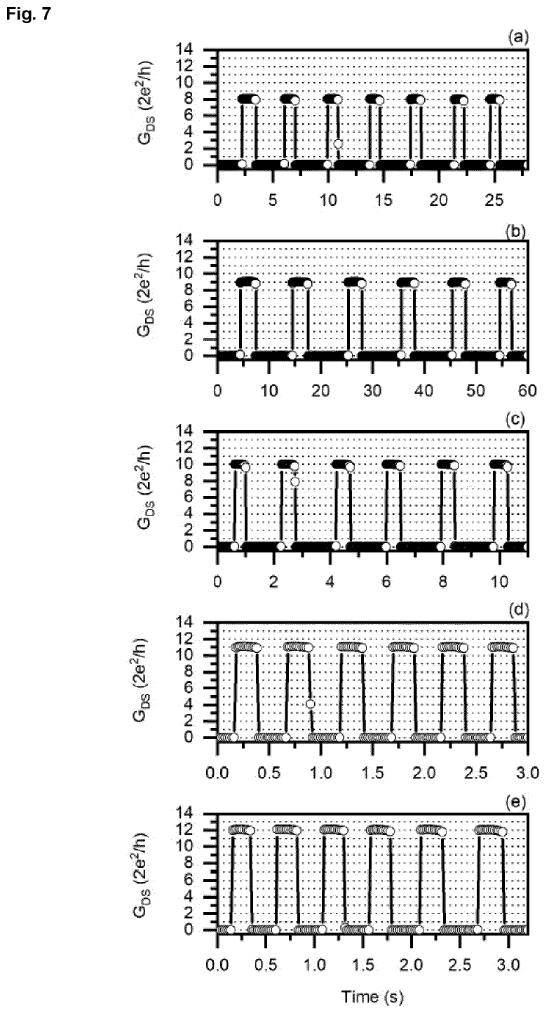

FIG. 7: Demonstration of bistable conductive switching between 0 and different integer quantum conductance levels (from 8 G₀ to 12 G₀) of an embodiment of the present invention.

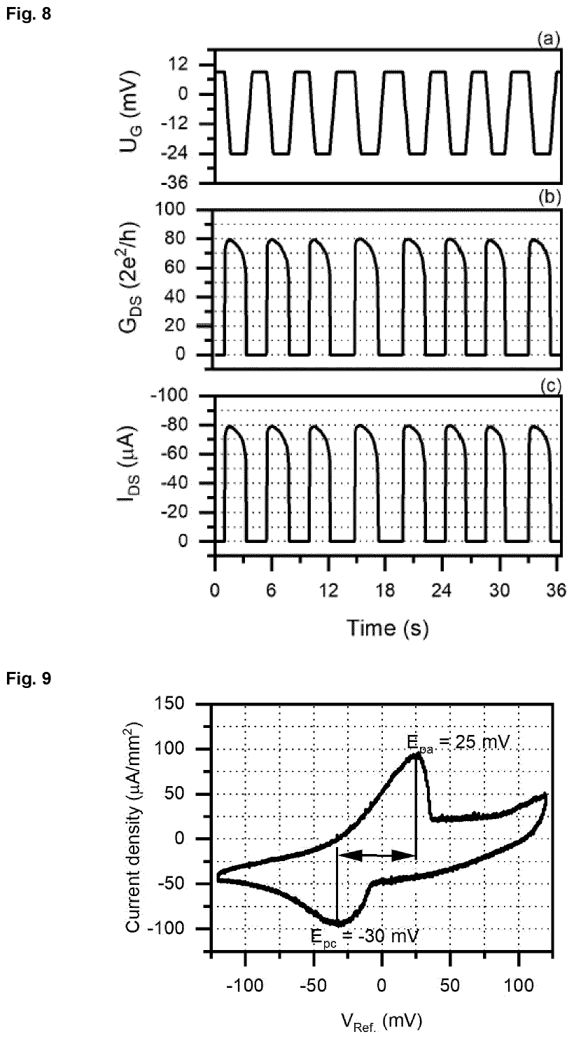

FIG. 8: Demonstration of high quantum conductance (80 G₀) and current switching controlled via the feedback mechanism in an atomic-scale tin transistor of an embodiment of the present invention.

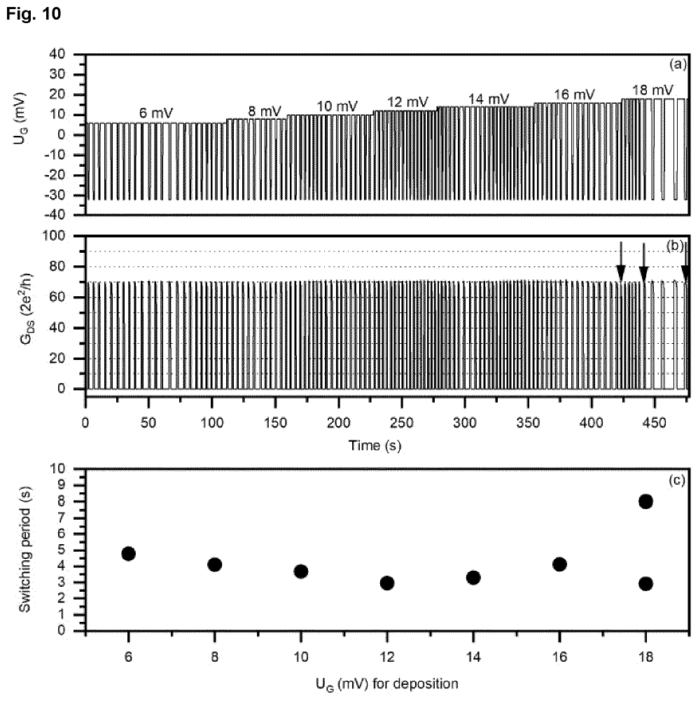

FIG. 9: Cyclic voltammogram of tin performed in the electrolyte of SnSO₄ (10 mM)+H₂SO₄ (40 mM) in bi-distilled water.

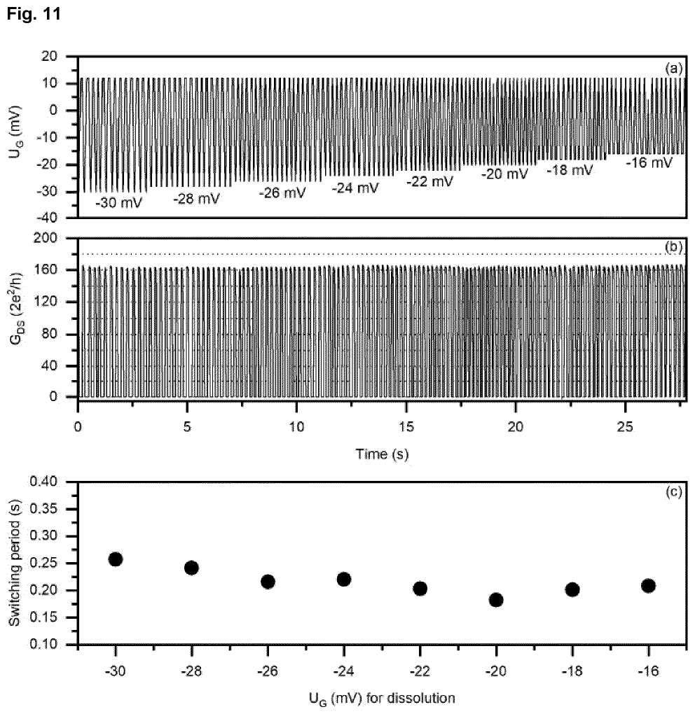

FIG. 10: Influence of the switching-on gate potential (U_{G}) on the operation behaviors of an atomic-scale tin transistor of the present invention.

FIG. 11: Influence of the switching-off gate potential (U_{G}) on the operation behaviors of a nano-scale tin transistor.

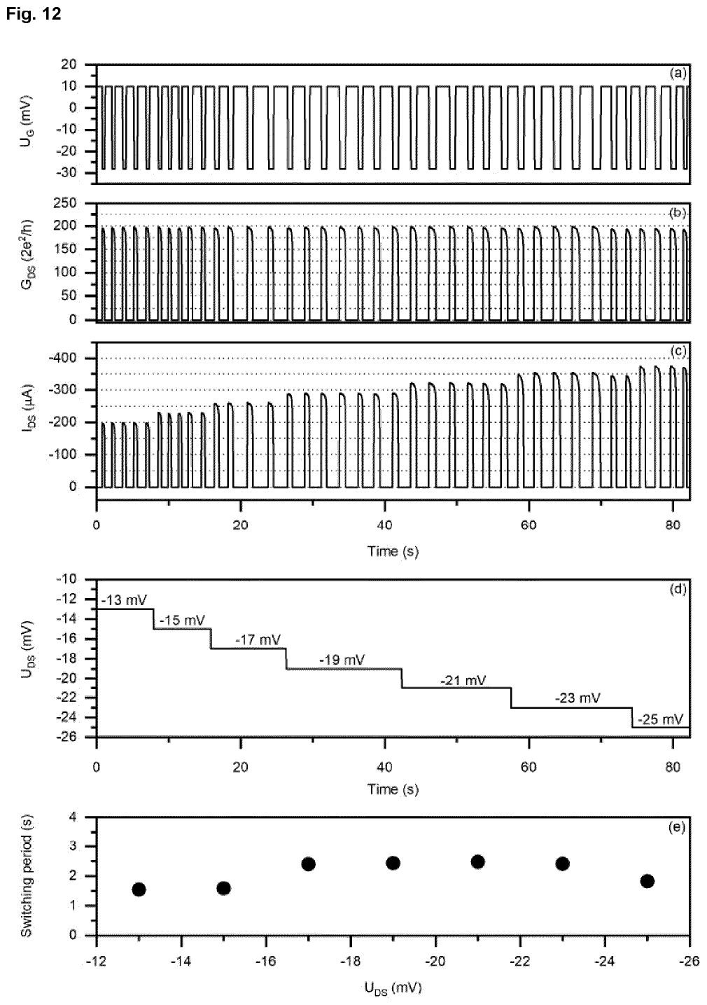

FIG. 12: Influence of the dc voltage applied across the drain and source electrodes (Ups) on the operation behaviors of an atomic-scale tin transistor of the present invention.

### EXPLANATION OF THE PROCEDURE AND THE COMPONENTS ACCORDING TO THE PRESENT INVENTION

As illustrated in FIG. 1, the atomic-scale tin transistor is a modified electrolytic cell. In the electrolytic cell, electrical potential energy is converted to chemical potential energy. The electrolytic cell uses an electric current to force a particular chemical reaction to occur, which would otherwise not take place. A standard electrolytic cell consists of two electrodes and an electrolyte. One of two electrodes is the anode, where oxidation takes place. The cathode is the electrode where reduction takes place. In the atomic-scale tin transistor according to the present invention, the gate electrode (3) is taken as one electrode and the combination of source (1) and drain (2) as another. The source electrode is grounded. A dc voltage of a bias voltage (U_{DS} or U_{Bias}) is applied to the drain electrode. When the gate potential (U_{G}) is larger than U_{DS} (U_{G}>U_{DS}), the gate electrode is the anode, and the combination of source and drain is the cathode. Some tin atoms on the surface of the gate are oxidized and dissolved as ions into the electrolyte (4) according to Equation (2):

$$Sn ( solid ) \to {Sn}^{2 +} ( a q . ) + 2 {e}^{-} \qquad ( 2 )$$

At the same time, an equal number of ions are reduced on the surface of the combination of the source and drain electrodes according to Equation (3):

$$S {n}^{2 +} ( a q . ) + 2 {e}^{-} \to Sn ( solid ) \qquad ( 3 )$$

Some nano- or microcrystals grow on the surfaces of both source and drain electrodes. Once the crystals are large enough, they meet each other in the gap between the source and drain, and form a tin point-contact (6), which is the switching unit in the atomic-scale tin transistor of the present invention. The zoom-in of the tin point-contact (6) is shown in FIG. 1 with an on-state model. As the U_{G}<U_{DS}, the functions of the gate and the combination of source and drain electrodes are reversed. The oxidation reaction takes place on the combination and the reduction on the gate. The tin point-contact is dissolved because of oxidation. When the U_{DS} is fixed, the tin point-contact can be built and dissolved reversibly by letting U_{G}>U_{DS} or U_{G}<U_{DS}.

The energy consumption in the atomic-scale tin transistor comes from electrochemically building and dissolving the tin point-contact between the source and drain. These building and dissolving procedures of the point-contact involve the material transfer of tin atoms amid the gate and the combination of source and drain. The minimal switching energy (E_{SW}) is estimated by the product of the number (N_{contact}) of tin atoms building the point-contact, two electrons needed by reducing Sn²⁺ ions, the potential difference between the gate and drain (U₁ (on) or U₂ (off) in volt), and one building and one dissolving procedure in a cycle. Therefore, the energy consumption of the atomic-scale tin transistor in one period is calculated as the sum of the dynamic and leakage parts according to Equation (4):

$${E}_{total} \approx {E}_{dynamic} + {E}_{leakage} = {\int }_{0}^{T} {I}_{G} {U}_{G} dt + {\int }_{0}^{T} {I}_{T} {U}_{DS} d \approx {N}_{contact} \cdot 2 \cdot e \cdot {U}_{1} + {N}_{contact} \cdot 2 \cdot e \cdot {U}_{2} + {\int }_{0}^{T} {I}_{t} {U}_{DS} dt , \qquad ( 4 )$$

where T is period T=1/f, f operation frequency, U_{DS} the dc voltage applied across the drain and source electrodes, IG is the electrochemical current between gate and drain-source, Iₜ is the tunneling current between the drain and source. The gap between the drain and source electrodes at the off-state in the atomic-scale tin transistor is calculated with the formula applied in electrochemical scanning tunneling microscopy (EC-STM) according to Equation (5) (cf. D. Woo et al., Surface Science 601, 1554-1559 (2007):

$${I}_{t} ( d ) = {AeU}_{DS} exp ( - 4 π \cdot \frac{\sqrt{2 m φ}}{h} \cdot d ) = {AeU}_{DS} exp ( - 1.025 \sqrt{φ} d ) \qquad ( 5 )$$

where A represents a constant, e represents electron charge, q represents the tunnel barrier in the electrolyte in volt, U_{DS} represents the voltage across the drain and source, and d represents the gap width in A. By considering the electrolyte concentration applied in the experiment, the tunnel barrier q is set at 1.6 V for further estimation. A tunneling regime with R_{T}<10⁷ (2 was assigned approximately to a substrate-tip separation range <1 nm in an EC-STM. With Equation (5), it is estimated that when the gap width increases 5.33 Å, the tunneling current should decrease by 1000 times. The tunneling current at off-state in the atomic-scale tin transistor was measured to be −1.7 nA when U_{DS} was set to −3.23 mV, and the quantum conductance at on-state measured to be 16 G₀. The gap is calculated to be 0.85 nm. The number of atoms (N_{contact}) in the point-contact in dimensions (length, 0.85 nm; diameter, 0.75 nm) with the conductance of 16 G₀ is calculated theoretically to be 80 at least.

In the atomic-scale tin transistor according to the present invention, the information carriers are tin atoms. Tin atoms as information carriers are considerably different from electrons or spins due to their natural weight and size. They are physically heavier and more massive. The mass ratio of a tin atom to an electron is 2.18×10⁵. The through-barrier-tunneling probability of the information carriers can be estimated using the Wentzel-Kramers-Brillouin (WKB) approximation according to Equation (6):

$${p}_{W K B} \approx exp ( - \frac{4 π \sqrt{2 m}}{h} \cdot L \cdot \sqrt{{E}_{b}} . ) , \qquad ( 6 )$$

where m denotes the carrier mass, L the barrier width, and E_{b} the barrier height. Considering both the “classic” over-barrier transition and “quantum” through-barrier tunneling, using atoms as information carriers has apparent advantages for L<2.5 nm. It has been confirmed both experimentally and theoretically that the conductive channel of the atomic-scale tin transistor according to the present invention can have geometrical dimensions of a few Å in diameter and ≤1 nm in length.

Different from the CMOS devices, the bit value is presented by the conductance of the point-contact in the atomic-scale tin transistor. However, in this case, information is easily transferred back to the electrical domain, where nearly all information processing takes place today. Therefore, the atomic-scale tin transistor fulfills the requirements, pointed out by K. Galatsi et al., IEEE transactions on Nanotechnology 8, 66-75 (2008) on an electronic device as an alternative to a CMOS device. The conductance of the tin point-contact as a physical state variable can reside in two distinguishable on/off states, can be controlled between the on/off states (write) by the gate potential, read by an electrical current through the tin point-contact, transmitted from one physical location to another via the electrical current, and initialized in a defined state (erase) just by setting the gate potential. It has been demonstrated that the conductance of the tin point-contact as a state variable can compete with the thermal noise bath at room temperature. Furthermore, the inner resistance of metallic atomic-scale transistors is ≤12.9 kΩ, much less than that of molecular electronic devices (in decades MΩ).

### Estimation of Energy Consumption in the Interconnects and Switching Process

The projected supply voltage (V_{DD}) and gate length (LG) at the technology node of “0.7 eq” in 2034 is 0.6 V and 12 nm, respectively. In charge-based CMOS logic circuits, the primary energy consumption source is electrical charging large capacitances in the interconnect wires. Indeed, transistor dynamic energy consumption constitutes ˜12% at the 10 nm technology node, and 88% of energy is dissipated in the interconnects. The atomic-scale tin transistors of the present invention as an alternative could offer benefits beyond charge-based CMOS. Because the dynamic energy consumption is proportional to V_{DD}², the energy consumption in the interconnect wires might be reduced by at least 400 times {[600 mV/abs (−30 mV)]²=400} or at maximum, 57600 times {[600 mV/abs (−2.5 mV)]²=57600} if the CMOS devices could be replaced with atomic-scale tin transistors. The potential values at −30 mV and −2.5 mV are the maximal applied voltages in absolute as illustrated in FIG. 2, FIG. 4a, and FIG. 4d.

In the atomic-scale tin transistor of the present invention with quantum conductance at 16 G₀, the minimal switching-on energy estimated with the first term in Equation (4) is 0.34 eV (13.1 k_{B}T at 300 K) when the reduction potential is 2.12 mV (0.5 mV-(−1.62)). The minimal energy is about 18.9 times larger than the ultimate limit on the minimum energy per switching at k_{B}TIn2 (Landauer's limit, approximately 3×10⁻²¹ J at room temperature). The maximal energy is estimated to be 3.99 eV (˜154.2 k_{B}T (at 300 K)) when the reduction potential of 24.91 mV (12 mV-(−12.91)) is taken from the switching sequence shown in FIG. 4a. However, the projected switching energy of a transistor at the technology node of “0.7 eq” is 193 k_{B}T (T at 300 K). The switching energy is about ˜1.25 times (193 k_{B}T/154.2 k_{B}T, at maximum) or 14.7 times (193 k_{B}T/13.1 k_{B}T, at minimum) larger than the switching energy of the atomic-scale tin transistor with the tin point-contact with quantum conductance of 16 G₀.

### Estimating the Equivalency of Driving Current in CMOS Devices and Atomic-Scale Tin Transistors

Fifteen switching sequences with different non-integer and integer quantum conductance are presented in FIGS. 5, 6, and 7. The quantum conductance varies from 1.2 G₀ to 12 G₀. Since U_{DS} was set at −12.91 mV, the corresponding on-state current (I_{DS}) through the devices changes from −1.2 μA to −12 μA. The I_{DS} presented in FIGS. 2, 3, 4a, and 8 were −14 μA, −7 μA, −16 μA, and ˜−80 μA, respectively. In an RC circuit, the time constant is t=RC=V/I·C. Therefore, the delay time (t_{d}) of a single CMOS inverter is calculated as:

$${t}_{d} = \frac{{C}_{s} \cdot {V}_{DD}}{{I}_{dsat}} \qquad ( 7 )$$

where Cₛ represents the total switching capacitance of a single inverter, I_{dsat} represents the driving current, V_{DD} represents the supply voltage. In the CMOS devices fabricated by Intel Company for its 10 nm technology node, I_{dsat} is 176 μA (NMOS) and 139 μA (PMOS), and V_{DD} 0.7 V, I_{off} 1 nA. The U_{DS} (−12.91 mV) in absolute is ˜54 times smaller than V_{DD} (0.7 V) in the 10 nm technology node. The I_{dsat} divided by 54 should be 3.24 μA (NMOS), 2.56 μA (PMOS), respectively. The I_{DS} from the atomic-scale tin transistor at −3 μA is comparable with the driving current of CMOS devices in the 10 nm technology node. The corresponding quantum conductance of the atomic-scale tin transistor is 3 G₀ when the U_{DS} is set at −12.91 mV. For logic operations, one “upstream” binary switch controls/communicates with several “downstream” binary switches. The number of downstream devices that are driven by a given upstream device is called “fan-out” (FO). A typical fan-out in logic circuits is three (FO3). If the atomic-scale tin transistor could be used as one “upstream” binary switch, the atomic-scale tin transistor should have quantum conductance at 9 G₀ and offer enough driving current at −9 μA with U_{DS} (−12.91 mV).

With the formula mentioned above of the time delay (ta), the equivalence of driving current can be built between the high-performance CMOS devices at the “5 nm” technology node [91.4 μA/device (on) and 1 nA/device (off), and V_{DD}=0.7 V] and the atomic-scale tin transistors (I_{DS}=−1.68 μA and U_{DS}=−12.91 mV).

### Fabricating and Training the Tin Point-Contact

FIG. 1 shows the schematic diagram of an atomic-scale tin transistor of the present invention. In the present embodiment, atomic-scale tin transistors are operated electrochemically in an electrochemical cell protected by an inert gas (Ar or N₂) environment. The source and drain electrodes are made of one noble metal such as gold, silver, copper, and platinum, for instance. Commonly known lithography methods can be employed. The gap size is between a few micrometers such as 2 μm to 10 μm (photolithography), and decades of nanometers such as 60 to 160 nm (e-beam lithography). The distance between the drain and gate may be several decades of nanometers. The source and drain electrodes are insulated with a polymer except a small window crossing both electrodes for the electrochemical deposition of tin. The gate electrode consists of a piece of tin wire (diameter of 0.5 mm, Puratronic®, 99.9985%) or a noble metal film covered with a layer of tin. For conductance measurements, a dc U_{DS} is applied to the drain electrode. The source electrode is virtually grounded via a trans-impedance circuit. The potential of the gate is changed with respect to the ground. Therefore, the potential differences between the gate, drain, and source are determined through U_{DS} and the gate potential. The source, drain, and gate are immersed in one kind of aqueous electrolytes containing tin salts and acids such as SnSO₄+H₂SO₄, SnCl₂+HCl, Sn(NO₃)₂+HNO₃, and SnSO₄+HBO₃.

To fabricate an initial tin point-contact in the gap between the source and drain, a potential at 30 mV is applied to the gate, and U_{DS} is set at −12.9 mV. While tin islands are deposited in the polymer-free window on the source and drain, the conductance between the source and drain is monitored. When two of the tin islands on the source and drain meet each other in the gap, an atomic-scale tin point-contact is built. After the first junction forms between the source and drain, the deposition procedure continues for some time to stabilize the junction.

After the initial stage, the contact is opened just by setting the gate potential in the range between −18 mV and −30 mV. Then, the freshly opened junction is closed again by setting the gate potential between 2 mV and 12 mV. The cyclic deposition/dissolution procedure trains the freshly built atomic-scale tin transistor with the feedback mechanism, which is similar to the one previously described for the atomic-scale Ag transistors in WO 2006/026961 A2. After the cyclic training procedure, the atomic-scale tin point-contact forms bistable configurations and can perform bistable quantum conductive switching between the source and drain. The sign and the magnitude of the dc voltage (U_{DS}) applied across these two electrodes directly influence the growth of the tin point-contact. Such a trained atomic-scale tin transistor can implement quantum conductance switching via both the feedback mechanism and a function generator. For comparison and consistency, the high conductance is indicated in the quantum conductance unit of G₀.

Following the gate potential via the feedback mechanism, FIG. 2 presents a high conductance (0 to 14 G₀) and current (0 to −14 μA) switching in one embodiment. FIG. 3 displays a virtual function-generator-controlled quantum conductance switching between 0 and 7 G₀ and current changing between 0 and −7 μA in another embodiment. The quantum conductance and the corresponsive current switching follow the variation of the gate potential in a delay in 0.1 s.

In the atomic-scale tin transistor, the potential differences between the gate, source, and drain are determined through U_{DS} applied between the drain and source and the gate potential U_{G}. It is valuable to investigate possible on/off potential ranges on the gate to fabricate energy efficient atomic-scale tin transistors. In the embodiment described as follows, the fabrication procedure of atomic-scale tin transistors consists of three steps: building tin point-contact, training the point-contact, reducing the absolute value of Ups, and decreasing the difference between U_{G} and U_{DS} from both upper and lower sides of Ups. At the first stage, an atomic-scale tin point-contact was built electrochemically in the gap between the source and drain electrodes fabricated with the photo or e-beam lithography by setting U_{G} at 30 mV and U_{DS} at −12.9 mV. The point-contact was stabilized at 30 mV for a few minutes afterwards. At the second stage, the cyclic training process started just after the temporal stabilization and continued till a bistable configuration formed in the tin point-contact. At the third stage, the magnitude of U_{DS} (−12.9 mV) was reduced by half, quarter, and one-eighth. After U_{DS} was set at a fixed value, the on/off potentials approached the U_{DS} from both upper and lower sides step by step. FIG. 4 illustrates four bistable switching sequences (0 to 16 G₀) achieved by setting Ups at −12.91 mV (a), −6.48 mV (b), −3.23 mV (c), −1.62 mV (d), individually. The corresponding on/off potentials (U_{G}) were 12/−30 mV (a), 2/−10 mV (b), 0/−4.5 mV (c), and 0.5/−2.5 mV (d). In a general tendency, the switching period increases as the magnitudes of U_{DS} and U_{G} decrease. The absolute current values were reduced by half, quarter, and one eighth when the magnitude of U_{DS} was decreased from −12.91 mV to −6.48 mV, −3.23 mV, and −1.62 mV, correspondingly. The values of current I_{DS} were −16 μA (a), −8 μA (b), −4 μA (c), and −2 μA (d), respectively.

In the embodiment shown in FIG. 4d, the potential difference between the gate and drain is 2.12 mV (on)/−0.88 mV (off), and the potential interval between the gate and source is 0.5 mV (on)/−2.5 mV (off). These on/off potentials illustrated in FIG. 4d are consistent with the formal reduction potential (−2.5 mV) roughly determined with the cyclic voltammetry displayed in FIG. 9.

The diversity of possible bistable atomic configurations in atomic-scale tin transistors has been confirmed in a series of embodiments under the investigation of the operation behavior of atomic-scale tin transistors via the feedback mechanism. The series of embodiments are presented in FIG. 5 (non-integer quantum conductance at on-states) and FIG. 6 (integer quantum conductance at on-states). In the ten embodiments shown in FIG. 5 and FIG. 6, U_{DS} was set at −12.91 mV. Ten switching sequences with seven cycles were selected as examples and presented each of the two figures. Because of comparison and clear presentation, the conductance is plotted on the same scale in each figure, but the scales are not the same for the two figures. The scales are −0.25-3 (FIG. 5), −0.5-7 (FIG. 6). Time axes vary to meet the time length of individual switching sequences. In FIG. 5, five graphs demonstrate that the atomic-scale tin transistors can implement operation between an “off-state” and “on-states” with non-integer quantum conductance at (a) 1.2 G₀, (b) 1.4 G₀, (c) 1.75 G₀, (d) 2.25 G₀, and (e) 2.5 G₀, respectively. The deposition/dissolution potentials for each switching sequence are 15/−35 mV (1.2 G₀), 15/−35 mV (1.4 G₀), 8/−24 mV (1.75 G₀), 10/−30 mV (2.25 G₀), and 10/−30 mV (2.5 G₀), separately. In FIG. 6, five digital wave plots illustrate the source-drain conductance switching between the non-conducting “off-state” and the conducting “on-state” with integer quantum conductance at (a) 2 G₀, (b) 3 G₀, (c) 4 G₀, (d) 5 G₀, and (e) 6 G₀, individually. The on/off potentials for each switching sequence are 8/−24 mV (2 G₀), 8/−24 mV (3 G₀), 8/−24 mV (4 G₀), 8/−24 mV (5 G₀), and 8/−24 mV (6 G₀), correspondingly. In FIG. 7, five graphs in rectangular waveform observed in five embodiments demonstrate the conductance switching sequences with on-states at (a) 8 G₀, (b) 9 G₀, (c) 10 G₀, (d) 11 G₀, and (e) 12 G₀, respectively. Since the plots utilize both line and empty circles (measured points), almost only direct transitions of closing edges were observed between these two states, and a few intermediate levels were found in the opening edges. This behavior is the same as that observed for the Pb atomic-scale transistors described previously. Thus, the results indicate that the switching transition of a tin point-contact is also due to a reproducible, bistable atomic-scale reconfiguration. The values of on/off switching potentials in each graph are 10/−30 mV (8 G₀), 10/−30 mV (9 G₀), 10/−30 mV (10 G₀), 8/−30 mV (11 G₀), and 8/−30 mV (12 G₀), correspondingly.

Following the gate potential via the feedback mechanism, FIG. 8 presents a high conductance (0 to 80 G₀) and current (0 to −80 μA) switching in one embodiment with U_{DS} set at −12.9 mV. The absolute value of the current in this embodiment is directly comparable with the driving current in the high-performance CMOS devices at the “5 nm” technology node [91.4 μA/device (on) and 1 nA/device (off), and V_{DD}=0.7 V]. The values of on/off switching potentials in FIG. 8a are 9/−24 mV.

### Using Cyclic Voltammetry to Determine the Formal Reduction Potential

Cyclic voltammetry was performed on one piece of gold wire in diameter of 0.25 mm as a working electrode and two pieces of tin wire in diameter of 0.5 mm as counter and quasi-reference electrodes. Within a sweeping range between-120 mV and 120 mV, the electrochemical potential was scanned reversibly at a rate of 4 mVs⁻¹ in the aqueous electrolytes of SnSO₄ (10 mM)+H₂SO₄ (40 mM). The cyclic voltammogram is plotted in FIG. 9 in the International Union of Pure and Applied Chemistry (IUPAC) convention. From the cyclic voltammogram, the cathodic peak potential (E_{pc}) is at −30 mV, and the anodic peak potential (Eₚₐ) is at 25 mV. According to cyclic voltammetry, the formal reduction potential (E°′) should be equal to (Eₚₐ+E_{pc})/2. Therefore, the formal reduction potential is determined with this cyclic voltammogram to be −2.5 mV. The electrochemical potential from the cyclic voltammogram can be translated into the potential applied to the gate electrode in the atomic-scale tin transistor, just multiplying the value by −1. The smallest reduction potential of tin is at ˜2.5 mV, which has been confirmed in FIG. 4d.

### Demonstration of Atoms Instead of Electrons as Information Carriers

To confirm the influence of the gate potential (U_{G}) and drain-source dc voltage (U_{DS}) on the operation behaviors of atomic-scale tin transistors, the switching-on gate potential, the switching-off gate potential, and the drain-source dc voltage were changed in the step of 2 mV in three experiments, respectively. The experimental results are presented in FIG. 10 (via variation of the switching-on gate potential, 0-70 G₀ switching), FIG. 11 (via variation of the switching-off gate potential, 0-166 G₀ switching), and FIG. 12 (via variation of U_{DS}, 0-197 G₀ switching).

Graph (a) of FIG. 10 shows the switching-on gate potential increasing from 6 mV to 18 mV at the step of 2 mV. Graph (b) illustrates the conductance switching between 0 and 70 G₀. Three arrows mark the change of switching period while the switching-on potential was kept constant. Graph (c) presents the switching periods as solid round points vs. the switching-on gate potential (U_{G}). While the gate potential varied from 6 mV to 18 mV at the step of 2 mV, the conductance at on-state kept constant at 70 G₀. The on-state electric current was −70 μA as the U_{DS} was set at −12.9 mV. The switching period decreased gradually when the switching-on potential increased from 6 mV to 12 mV and increased minorly when the potential varied from 12 mV to 16 mV. When the gate potential was set at 18 mV, the switching period jumped from low to higher level as marked with three arrows in Graph (b). Thus, although the conductance kept the same, the configuration of the tin point-contact changed during switching.

Graph (a) of FIG. 11 shows the switching-off gate potential increasing from −30 mV to −16 mV at the step of 2 mV. In the middle, Graph (b) illustrates the conductance switching between 0 and 166 G₀. At the bottom, Graph (c) presents the switching periods as solid round points vs. the gate potential. The on-state electric current was −166 μA as the U_{DS} was set at −12.9 mV. The switching period decreased gradually when the switching-off gate potential increased from −30 mV to −20 mV at the step of 2 mV, and then raised minorly when the gate potential changed forward from −20 mV to −16 mV.

Graph (a) of FIG. 12 shows the gate potential switching between-28 mV (switching-off) and 10 mV (switching-on). Graph (b) illustrates the conductance switching between 0 and 197 G₀. Graph (c) presents the switching current through the drain and source electrodes. The switching-on current in magnitude increases as the absolute value of U_{DS} increases. Graph (d) displays the stepwise change of U_{DS} from −13 mV to −25 mV at the step of −2 mV. Finally, graph (e) demonstrates the switching period as solid round points vs. the drain-source do voltage. Thus, the drain-source dc voltage influences the switching period.

Because the atomic-scale tin transistors perform bistable conductance switching, the conductance at on-states in these three figures keeps constant during variation of the gate potentials and the drain-source dc voltage. However, the variation of the gate potential and the drain-source dc voltage influences the switching period. The electric current at on-states does not depend on the gate potential during bistable conductance switching. Since the atomic-scale tin transistor has metallic point-contact at on-state, its I-V characteristic is Ohmic. The electric current at on-state is linearly proportional to the drain-source dc voltage as the graph of FIG. 12c indicates. The current changes (I_{DS}) from −197 μA to −376 μA when U_{DS} varies from −13 mV to −25 mV. The constant conductance at on-states in these three experiments demonstrates that the bistable configurations are robust. Therefore, atoms instead of electrons are information carriers in the atomic-scale tin transistors of the present invention.

The diversity of the bistable atomic configurations with different quantum conductance (from 1.2 G₀ to 197 G₀) in the atomic-scale tin point-contacts has been confirmed. The on-state current (I_{DS}) through the devices changes from −1.2 μA to −375 μA. The on/off current ratio can reach 2.2×10⁴. With the formula of the time delay (ta) in a single CMOS inverter, the equivalence of driving current can be built between the CMOS devices at the “5 nm” technology node and the atomic-scale tin transistors of the present invention. The I_{DS} from the atomic-scale tin transistor at −1.68 μA (U_{DS}=−12.91 mV) is comparable with the driving current [91.4 μA/device (on) and V_{DD}=0.7 V] of CMOS devices at the “5 nm” technology node.

1. An atomic-scale tin transistor device comprising:
a source electrode;
a drain electrode; and
a gate electrode,
wherein the source, drain, and gate electrodes are spaced apart from one another and immersed in an aqueous electrolyte containing tin ions in an electrochemical cell,
wherein the source electrode and drain electrode are connected to each other in an on-state by a bistable atomic-scale tin point-contact which can be reversibly opened and closed by dissolution/deposition potentials applied to the gate electrode, respectively, and
wherein the atomic-scale tin point-contact consists in the on-state at its narrowest point of at least one tin atom up to a few hundreds of tin atoms formed by electrochemical deposition of tin.

2. The tin transistor device according to claim 1, wherein the source and drain electrodes contain at least one metal selected from the group consisting of copper (Cu), ruthenium (Ru), rhodium (Rh), palladium (Pd), osmium (Os), iridium (Ir), platinum (Pt), gold (Au), and silver (Ag).

3. The tin transistor device according to claim 1, wherein the gate electrode consists of a tin wire or a metal film covered with a layer of tin.

4. The tin transistor device according to claim 1, wherein the electrolyte is an aqueous electrolyte comprising tin salts and acids such as SnS04+H2SO4, SnCh+HCl, Sn(NO₃)₂+HNO₃, and SnS0₄+HBO₃.

5. The tin transistor device according to claim 1, wherein the conductive channel length is 3 nm or less, preferably 1 nm or less.

6. The tin transistor device according to claim 1, wherein the only movable parts of which are the tin atoms, which connect the source and drain electrodes.

7. The tin transistor device according to claim 1, wherein the gate potential is less than 35 mV in magnitude.

8. The tin transistor device according to claim 1, wherein the tunneling current at an off-state is less than 10 nA.

9. A method of producing an atomic-scale tin transistor device according to claim 1, comprising:
repeatedly applying potential cycles between the gate electrode and the source or drain electrode, respectively, for repeatedly depositing and dissolving tin atoms between the source electrode and drain electrode until the bistable atomic-scale tin point-contact has been formed,
wherein the potential during the potential cycles is increased and subsequently lowered as long as due to the change of the potential at the gate electrode, the conductance value between the source electrode and the drain electrode is reproducibly switchable between two conductance values as a function of the potential of the gate electrode.

10. The method according to claim 9, wherein the bistable atomic-scale tin point-contact in the on-state at its narrowest point consists of only one tin atom or of a few tin atoms, and wherein by means of the tin transistor device an electrical circuit is opened or closed through conductive switching between on/off states within the atomic-scale tin point-contact with the bistable configuration by deposition/dissolution potentials in millivolts applied to the gate electrode.

11. The method according to claim 9, wherein the cycling process is carried out between two or more specified gate electrode potentials, and wherein the potential is varied in a rectangular, triangle, trapezoid, or sinusoidal waveform.

12. Use of the atomic-scale tin transistor device according to claim 1 as an atomic transistor or atomic relay.

13. The use according to claim 12 for logic switches and/or carrying out logic operations.

14. The use according to claim 12, wherein the transistor or relay is used in the range of ultra-high frequencies from the megahertz range over the gigahertz range to the terahertz range.

15. The use according to claim 12 as building blocks of atom-based electronics.
